(19) United States
(12) Patent Application Publication
(10) Pub. No.: US 2025/0130770 A1
(43) Pub. Date: Apr. 24, 2025

(54) Mixed Sign Multiplier Devices and Methods

(71) Applicant: Xilinx, Inc., San Jose, CA (US)

(72) Inventor: Chinmaya Dash, Hyderabad (IN)

(21) Appl. No.: 18/493,233

(22) Filed: Oct. 24, 2023

(51) Int. Cl. G06F 7/523; G06F 5/01; G06F 7/50; H03K 19/21

(52) U.S. Cl. CPC G06F 7/523; G06F 5/01; G06F 7/50; H03K 19/21

(57) ABSTRACT

An implementation may include a method for performing a binary multiplication including receiving a first at an input interface of a digital multiplier circuit in the computing system, receiving a second operand at the input interface of the digital multiplier circuit, generating, by the digital multiplier circuit, partial products by performing a AND operation with each of the N bits of the first operand and each of the bits of the second operand, and generating first modified partial products by modifying, by the digital multiplier circuit, most significant bits of the partial products, generating second modified partial products by modifying, by the digital multiplier circuit, one of the first modified partial product, generating, by the digital multiplier circuit, a product by summing the second modified partial products, and outputting the product from an output interface of the digital multiplier circuit.

### TECHNICAL FIELD

The present invention relates generally to binary multiplier circuits, and, in particular implementations, mixed sign binary multiplier methods and systems for multiplying signed or unsigned binary numbers.

### BACKGROUND

With the advent of technologies that require complex and fast data processing, digital systems have evolved to perform large numbers of mathematical operations in less time. Since multiplication is a basic form of mathematical operation performed by a digital system, different algorithms, such as Booth's multiplication algorithm, have been developed to reduce the time for a digital system to multiply two numbers.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a dot diagram of an example method of binary multiplication in accordance with implementations of the disclosure;

FIG. 2 illustrates a schematic diagram of a binary multiplier circuit in accordance with implementations of the disclosure;

FIG. 3 illustrates a block diagram of a binary multiplier circuit in accordance with implementations of the disclosure;

FIG. 4 is a block diagram of an example device in which one or more features of the disclosure can be implemented; and

FIG. 5 is a flowchart illustrating a binary multiplication method in accordance with implementations of the disclosure.

Corresponding numerals and symbols in the different figures generally refer to corresponding parts unless otherwise indicated. The figures are drawn to clearly illustrate the relevant aspects of the implementations and are not necessarily drawn to scale. The edges of features drawn in the figures do not necessarily indicate the termination of the extent of the feature.

### DETAILED DESCRIPTION OF ILLUSTRATIVE IMPLEMENTATIONS

The making and using of various implementations are discussed in detail below. It should be appreciated, however, that the various implementations described herein are applicable in a wide variety of specific contexts. The specific implementations discussed are merely illustrative of specific ways to make and use various implementations, and should not be construed in a limited scope. Throughout the discussion herein, unless otherwise specified, the same or similar reference numerals or labels in different figures refer to the same or similar component or signal.

Reference to “an implementation,” “one implementation,” “an embodiment,” or “one embodiment” in the framework of the present description is intended to indicate that a particular configuration, structure, or characteristic described in relation to the implementation/embodiment is included in at least one implementation/embodiment. Hence, phrases such as “in one implementation” or “in one embodiment” that may be present in one or more points of the present description do not necessarily refer to one and the same implementation/embodiment. Moreover, particular conformations, structures, or characteristics may be combined in any adequate way in one or more implementations/embodiments. The references used herein are provided merely for convenience and hence do not define the extent of protection or the scope of the implementations/embodiments.

Digital multipliers are fundamental elements in computer arithmetic, pivotal in a myriad of applications from scientific computing to signal processing. Over time, various techniques have emerged for efficiently executing binary multiplication. Methods like long multiplication, Booth's algorithm, and tree multipliers such as Wallace and Dadda trees have been developed to improve computational efficiency. There are also hardware-specific solutions like lookup tables and shift operations that offer advantages in specific scenarios.

Despite these advancements, existing multipliers have several drawbacks. They often suffer from latency issues that can hinder performance in real-time and high-speed applications. They also can be power-intensive, making them less ideal for battery-operated and portable systems. The hardware implementations for some of these efficient algorithms can consume significant silicon area, increasing manufacturing costs. Complexity and scalability are additional concerns, as many existing algorithms and hardware solutions are not easily adaptable to handle different operand sizes or a large number of bits without affecting performance or power consumption negatively.

As an example, for 4-bit multiplication, the 4-bit number (INT4) can be a signed or unsigned number. Depending on the signedness, the 4 bits represent a certain number. Table 1 below shows the possible number values depending on signedness for an INT4 number.

TABLE 1

| 4-bits | Value when declared | Value when declared |
|---|---|---|
| of INT4 | as unsigned | as signed |
| 0000 | 0 | 0 |
| 0001 | 1 | 1 |
| 0010 | 2 | 2 |
| 0011 | 3 | 3 |
| 0100 | 4 | 4 |
| 0101 | 5 | 5 |
| 0110 | 6 | 6 |
| 0111 | 7 | 7 |
| 1000 | 8 | −8 |
| 1001 | 9 | −7 |
| 1010 | 10 | −6 |
| 1011 | 11 | −5 |
| 1100 | 12 | −4 |
| 1101 | 13 | −3 |
| 1110 | 14 | −2 |
| 1111 | 15 | −1 |

Thus, a 4-bit number can represent numbers in a range from −8 to 15. Such numbers are frequent in computation requirements for artificial intelligence (AI) Engines, central processing units (CPUs), graphics processing units (GPUs), etc. Although the examples primarily discussed in this disclosure are 4-bit integers (INT4), the present disclosure is not limited hereto, and other number types are within the scope of this disclosure. For example, multiplying INT8, INT16, 8-bit floating point (FP8), FP16, or the like are within the scope of this disclosure.

In conventional systems, multipliers are optimized for a specific signedness of inputs—e.g., there are multipliers that can multiply two signed numbers, or two unsigned numbers. Such multipliers do not work for other combinations of signedness. A 4-bit unsigned multiplier does not work for 4-bit signed inputs, similarly, a 4-bit signed multiplier does not work for 4-bit unsigned inputs.

In conventional systems, for multiplication with scenarios with combinations of signedness (e.g., a signed number and an unsigned number), the INT4 numbers are first converted to 5-bit signed numbers. 5-bit signed numbers have a range from −16 to 15 which can cover the required range of −8 to 15. The multiplication is then performed using 5-bit signed multiplication. Thus, the multipliers for the conventional systems have to be made at least one bit larger to attempt to account for the mixed signed multiplication.

As another example, in conventional systems, a single multiplier is designed to be used for multiple different datatypes. An example can be that the same multiplier needs to function for FP16 and INT8 datatypes. For FP16, an unsigned 11×11 multiplier is needed. For INT8, a signed 8×8 multiplier is needed. A signed 8×8 multiplier is not a subset of unsigned 11×11 multiplication. Thus, in conventional systems, a signed 12×12 multiplier would be required to handle both FP16 and INT8 datatypes-which adds area and power and diminishes the speed of the circuit.

In contrast to the conventional systems and methods previously discussed, the described methods and systems have the benefit that this multiplier circuit is more efficient in power, performance, and area compared to other known circuits. For example, the disclosed implementations of the mixed sign multiplier, when compared to current multipliers, reduces the required area by 11.6% while using 28% less power. Moreover, the disclosed multiplier is able to handle inputs of any signedness (both signed, both unsigned, and one signed and one unsigned).

Further, using the example above for a single multiplier to handle FP16 and INT8 datatypes, with the disclosed implementations, a single mixed sign 11×11 multiplier can be used—as signed 8×8 multiplication is a subset of this multiplier.

In addition, the correction factor of each multiplication need not be added to the partial products. A pre-computed correction factor for several multiplications can be added where the multiplication results are being summed. This further reduces the circuit size, improving power, performance, and area.

The disclosed implementations of the mixed sign multiplier may be used in an application-specific integrated circuit (ASIC), a field-programmable gate array (FPGA), a CPU, a GPU, a general-purpose computing on GPU (GPGPU), an AI engine, a digital signal processing (DSP) system, a neural network, or the like.

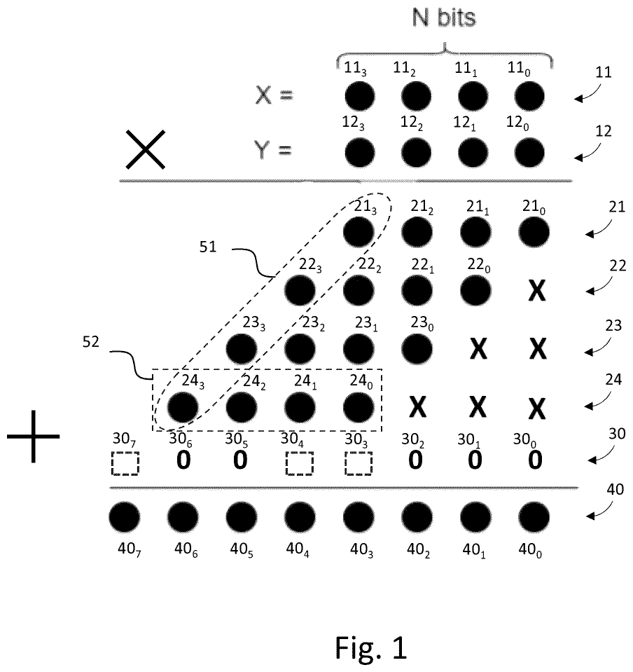

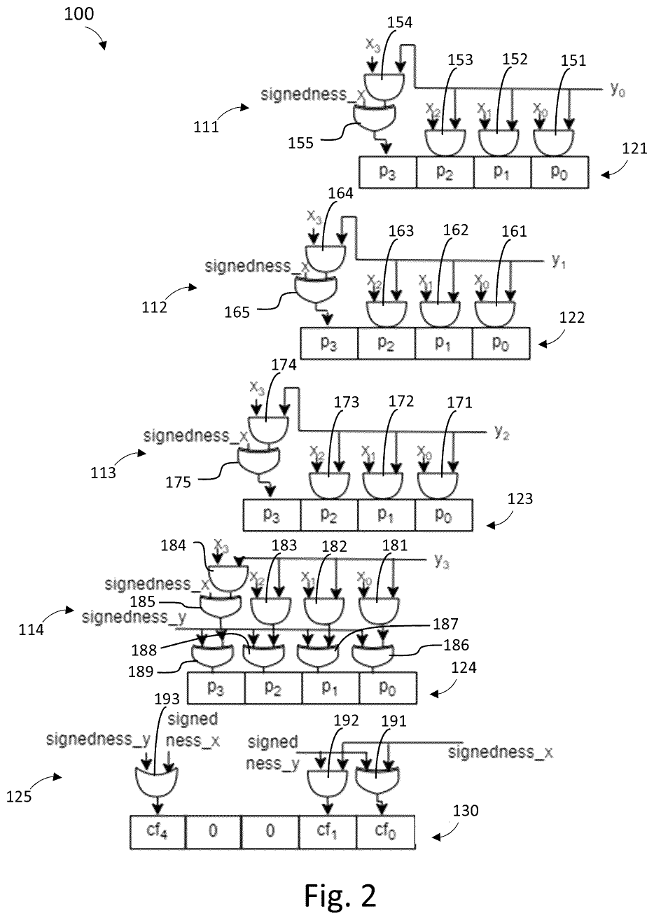

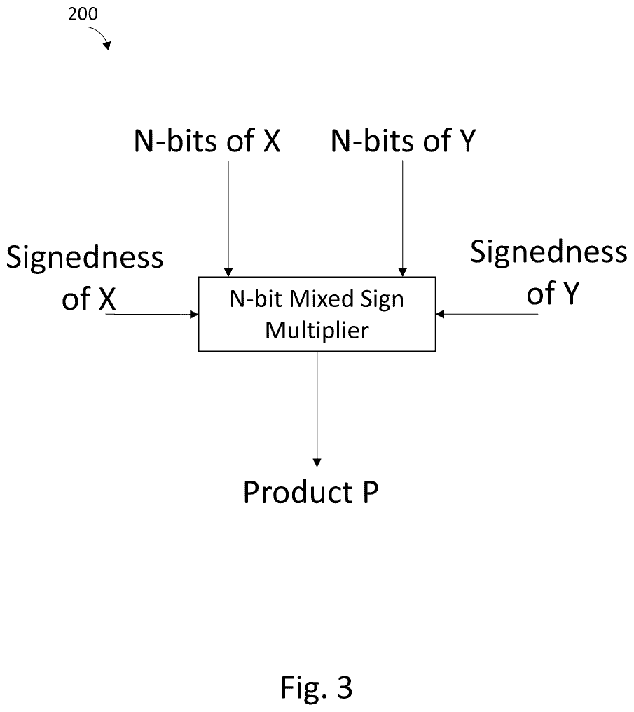

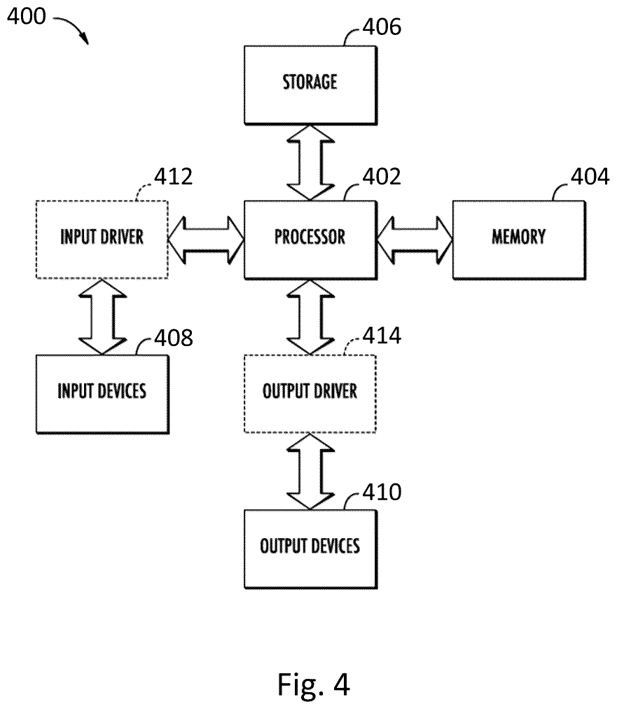

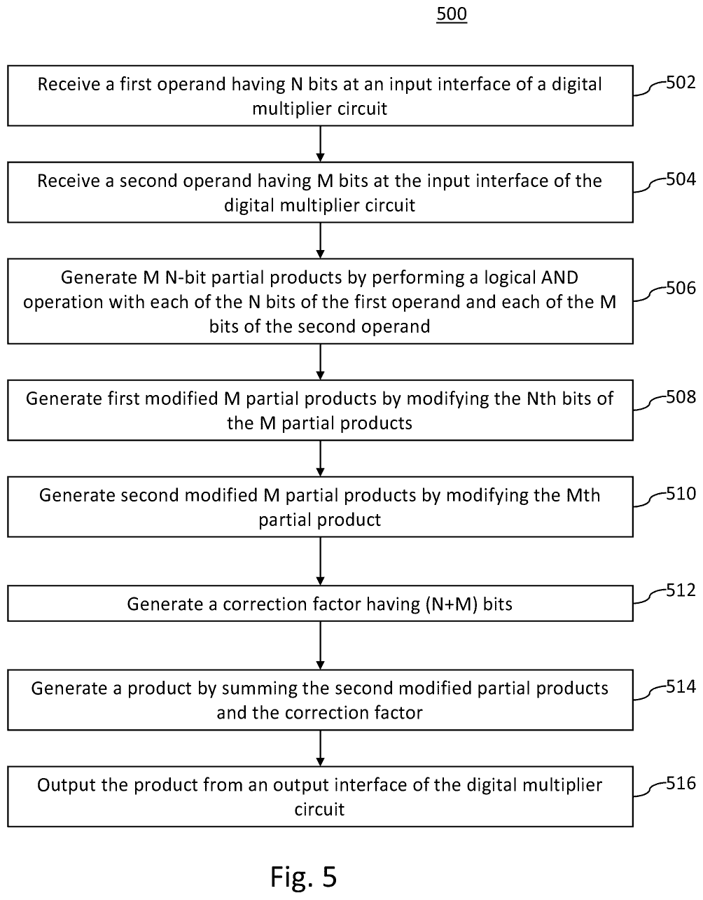

Implementations provided below describe various methods and systems for a mixed sign multiplier, and in particular implementations, methods and systems for a mixed sign multiplier with low power and area requirements with improved performance. The following description describes the implementations. FIG. 1 is used to describe an example method and system. A circuit diagram of an example method and system is described using FIG. 2. A block diagram of an example method and system is described using FIG. 3. FIG. 4 describes an example device to implement the methods and system for the disclosed mixed sign multiplier. An example method for mixed sign multiplication is described using FIG. 5.

FIG. 1 illustrates a dot diagram of a method of binary multiplication in accordance with one or more implementations of the present disclosure. In the example shown in FIG. 1, a first binary operand 11 (X) and a second binary operand 12 (Y) will be multiplied. Each of the first and second operands 11, 12 may have the same number of bits, for example, each of the first and second operands 11, 12 may have N-bits. As shown in the example of FIG. 1, the operands 11, 12 are 4-bit operands; however, the present disclosure is not limited thereto, and in various implementations, the operands 11, 12 may have any number of bits. With 4-bit operands, as shown, the first operand 11 includes a least significant bit (LSB) or zeroth bit 11₀, a first bit 11₁, a second bit 11₂, and a most significant bit (MSB) or third bit 11₃. Similarly, the second operand 12 includes an LSB or zeroth bit 12₀, a first bit 12₁, a second bit 12₂, and an MSB or third bit 12₃.

A first N-bit partial product 21 is obtained by performing logical AND operations with the zeroth bit or least significant bit 12, of the second operand 12 and each of the N bits of the first operand 11. For example, as shown, the first partial product 21 is an N-bit number (in this example, a 4-bit number) having a least significant bit or zeroth bit 210 obtained by performing a logical AND operation with the zeroth bit 12₀ of the second operand 12 and the zeroth bit 11₀ of the first operand 11 as inputs. The first partial product 21 has a first bit 21₁ obtained by performing a logical AND operation with the zeroth bit 12₀ of the second operand 12 and the first bit 11, of the first operand 11 as inputs. A second bit 21₂ of the first partial product 21 is obtained by performing a logical AND operation with the zeroth bit 12₀ of the second operand 12 and the second bit 11₂ of the first operand 11 as inputs. An MSB or third bit 21₃ of the first partial product 21 is obtained by performing a logical AND operation with the zeroth bit 12₀ of the second operand 12 and the third bit 11₃ of the first operand 11 as inputs.

Each of the N-bit partial products may be obtained by a similar process as described above with respect to the first partial product 21, with each of the subsequent partial products being left-shifted one bit position with respect to the prior partial product, as will be described in further detail below.

A second N-bit partial product 22 may be obtained by performing logical AND operations with the N-2 bit (in this example, the first bit 12₁) of the second operand 12 and each of the N bits of the first operand 11. In the example shown in FIG. 1, the second partial product 22 has a zeroth bit 22, obtained by performing a logical AND operation with the first bit 12, of the second operand 12 and the zeroth bit 11₀ of the first operand 11 as inputs. The first bit 22₁ of the second partial product 22 is obtained by performing a logical AND operation with the first bit 12₁ of the second operand 12 and the first bit 11₁ of the first operand 11 as inputs. The second bit 22₂ of the second partial product 22 is obtained by performing a logical AND operation with the first bit 12₁ of the second operand 12 and the second bit 11₂ of the first operand 11 as inputs. The third bit 22₃ of the second partial product 22 is obtained by performing a logical AND operation with the first bit 12₁ of the second operand 12 and the third bit 11₃ of the first operand 11 as inputs.

The third N-bit partial product 23 may be obtained by performing logical AND operations with the N-1 bit (in this example, the second bit 12₂) of the second operand 12 and each of the N bits of the first operand 11. In the example shown in FIG. 1, the third partial product 23 has a zeroth bit 23₀ obtained by performing a logical AND operation with the second bit 12₂ of the second operand 12 and the zeroth bit 11₀ of the first operand 11 as inputs. The first bit 23₁ of the third partial product 23 is obtained by performing a logical AND operation with the second bit 12₂ of the second operand 12 and the first bit 11, of the first operand 11 as inputs. The second bit 23₂ of the third partial product 23 is obtained by performing a logical AND operation with the second bit 12₂ of the second operand 12 and the second bit 11₂ of the first operand 11 as inputs. The third bit 23₃ of the third partial product 23 is obtained by performing a logical AND operation with the second bit 12₂ of the second operand 12 and the third bit 11₃ of the first operand 11 as inputs.

The fourth N-bit partial product 24 may be obtained by performing logical AND operations with the N-1 bit (in this example, the third bit 12₃) of the second operand 12 and each of the N bits of the first operand 11. In the example shown in FIG. 1, the fourth partial product 24 has a zeroth bit 24₀ obtained by performing a logical AND operation with the third bit 12₃ of the second operand 12 and the zeroth bit 11₀ of the first operand 11 as inputs. The first bit 24₁ of the fourth partial product 24 is obtained by performing a logical AND operation with the third bit 12₃ of the second operand 12 and the first bit 11, of the first operand 11 as inputs. The second bit 24₂ of the fourth partial product 24 is obtained by performing a logical AND operation with the third bit 12₃ of the second operand 12 and the second bit 11₂ of the first operand 11 as inputs. The third bit 23₃ of the fourth partial product 24 is obtained by performing a logical AND operation with the third bit 12₃ of the second operand 12 and the third bit 11₃ of the first operand 11 as inputs.

Further, an exclusive or (XOR) function 51 is applied to each of the third bits of the partial products 21-24. In some implementations, the XOR function 51 applies an XOR logic function to each of the third bits of the partial products 21-24 (21₃, 22₃, 23₃, 24₃) with the signedness of the first operand (X). In addition, an XOR function 52 is applied to each of the bits of the fourth partial product 24. In some implementations, the XOR function 52 applies an XOR logic function to each of the bits of the fourth partial product 24 (24₀, 24₁, 24₂, 24₃) with the signedness of the second operand (Y).

Further, as shown in FIG. 1, a correction factor 30 is generated in accordance with one or more embodiments. The correction factor 30 includes 2N bits, which in the illustrated example is 8 bits. The bit mask of the correction factor 30 can be given by the formula below: Correction Factor={OR of signednesses, N-2 zeroes, AND of signednesses, XOR of signednesses, N-1 zeroes}.

More generally, for an N×M multiplication, the correction factor is (N+M) bits. It is given by Correction Factor={OR of signednesses, N-2 zeroes, AND of signednesses, XOR of signednesses, M-1 zeroes}.

In the illustrated example of FIG. 1, the seventh bit 30₇ of the correction factor 30 is obtained by performing a logical OR operation with the signedness of the first and second operands 11, 12 as inputs. The signedness of a signed number is 1 and the signedness of an unsigned number is 0. The seventh bit 30₇ of the correction factor 30 is followed by N-2 zeroes. In the illustrated example, the number N is equal to 4, and thus 2 zeros follow the seventh bit 30₇, as the seventh and fifth bits 30₆, 30₅ of the correction factor 30. Following the N-2 zeroes, the next bit of the correction factor 30 (here, the fourth bit 30₄) is obtained by performing a logical AND operation with the signedness of the first and second operands 11, 12 as inputs. The next bit of the correction factor 30 (here, the third bit 30₃) is obtained by performing an exclusive OR operation with the signedness of the first and second operands 11, 12 as inputs. Finally, the correction factor 30 includes N-1 zeroes, which in the illustrated example is provided by 3 zeroes in the third, second, and zeroth bits 30₂, 30₁, 30₀ of the correction factor 30.

The product 40 is obtained by performing binary addition operation of all the partial products 21-24 and the correction factor 30. The partial products 21-24 are unsigned numbers while the correction factor is a signed number. The product 40 is unsigned if both operands 11,12 are unsigned. If any of the operands 11, 12 are signed numbers, the product 40 is also a signed number.

The zeroth bit 40₀ of the product 40 is obtained by performing a binary addition operation with the zeroth bit 21, of the partial product 21 and the correction factor bit 30₀ as inputs. Alternatively, the zeroth bit 40₀ of the product 40 may simply be provided as having the value of the zeroth bit 21₀ of the partial product 21, as the other bits in the and the correction factor bit 30₀ is zero.

The first bit 40₁ of the product 40 is obtained by performing a binary addition of the partial product bits 21₁ and 22₀ and the correction factor bit 30₁, and any carry value from the lower bit values, which is zero in this case. The lower bit of the sum is the value of the respective bit of the product 40 and the higher bit of the sum is forwarded as carry for next addition.

The second bit 40₂ of the product 40 is obtained by performing a binary addition of the partial product bits 21₂, 22₁, 23₀, and the correction factor bit 30₂, and any carry value from the lower bit values. The lower bit of the sum is the value of the respective bit of the product 40 and the higher bit of the sum is forwarded as carry for next addition.

The third bit 40₃ of the product 40 is obtained by performing a binary addition of the partial product bits 21₃, 22₂, 23₁, 24₀, and the correction factor bit 303, and any carry value from the lower bit values. The lower bit of the sum is the value of the respective bit of the product 40 and the higher bit of the sum is forwarded as carry for next addition.

The fourth bit 40₄ of the product 40 is obtained by performing a binary addition of the partial product bits 22₃, 23₂, 24₁, and the correction factor bit 30₄, and any carry value from the lower bit values. The lower bit of the sum is the value of the respective bit of the product 40 and the higher bit of the sum is forwarded as carry for next addition.

The fifth bit 40₅ of the product 40 is obtained by performing a binary addition of the partial product bits 23₃, 24₂, and the correction factor bit 30₅, and any carry value from the lower bit values. The lower bit of the sum is the value of the respective bit of the product 40 and the higher bit of the sum is forwarded as carry for next addition.

The sixth bit 40₆ of the product 40 is obtained by performing a binary addition of the partial product bit 24₃, the correction factor bit 30₆, and any carry value from the lower bit values. The lower bit of the sum is the value of the respective bit of the product 40 and the higher bit of the sum is forwarded as carry for next addition.

The seventh bit 40₇ of the product 40 is obtained by performing a binary addition of the correction factor bit 30₇ and any carry value from the lower bit values.

The product 40 is a 2N bit value, where N is the number of bits of the operands 11, 12. Thus, as shown in FIG. 1, the product 40 is an 8-bit value and each of the first and second operands 11, 12 are 4-bit values. In some embodiments, the operands have a different number of bits. For example, the operand 11 has N bits and the operand 12 has M bits. In these embodiments, there will be M N-bit partial products and the product 40 with be a (N+M) bit value number.

FIG. 2 is a schematic diagram illustrating a binary multiplication circuit 100 in accordance with one or more implementations of the present disclosure. The circuit 100 is configured to perform binary multiplication by implementing the method described previously herein with respect to FIG. 1. In the example shown in FIG. 2, a first binary operand X (x₃, x₂, x₁, x₀) and a second binary operand Y (y₃, y₂, y₁, y₀) will be multiplied. The first binary operand may be similar to the first operand 11 described above and the second binary operand Y may be similar to the second operand 12 described above. The circuit 100 is described below with respect to performing binary multiplication on 4-bit operands; however, the present disclosure is not limited thereto, and in various implementations, the operands may have any number of bits. In some embodiments, the operands may have different numbers of bits, such that for example, the first binary operand X has N number of bits and the second binary operand has M number of bits, with M being different than N.

As shown in FIG. 2, the circuit 100 includes a first partial product circuit 111 configured to generate a first partial product 121, a second partial product circuit 11₂ configured to generate a second partial product 122, a third partial product circuit 11₃ configured to generate a third partial product 123, and a fourth partial product circuit 114 configured to generate a fourth partial product 124. The circuit 100 further includes a correction factor circuit 125 configured to generate a correction factor 130.

The first partial product circuit 111 includes a plurality of logic gates configured to generate the first partial product 121. In particular, a first AND logic gate 151 receives as input the zeroth bit x₀ of the first operand X and the zeroth bit y₀ of the second operand Y, and generates as output a zeroth bit p₀ of the first partial product 121. A second AND logic gate 152 receives as input the first bit x₁ of the first operand X and the zeroth bit y₀ of the second operand Y, and generates as output a first bit p₁ of the first partial product 121. A third AND logic gate 153 receives as input the second bit x₂ of the first operand X and the zeroth bit y₀ of the second operand Y, and generates as output a second bit p₂ of the first partial product 121. A fourth AND logic gate 154 receives as input the third bit x₃ of the first operand X and the zeroth bit y₀ of the second operand Y. The output of the fourth logic gate 154 is provided as input to an XOR logic gate 155. The XOR logic gate 155 further receives as input the signedness of the first operand X (signedness_x), and generates as output a third bit p₃ of the first partial product 121.

The first partial product 121 may be stored in any suitable computer-readable storage medium, including in a wire, register, computer-readable memory, or the like.

The second partial product circuit 11₂ includes a first AND logic gate 161 that receives as input the zeroth bit x₀ of the first operand X and the first bit y, of the second operand Y, and generates as output a zeroth bit p₀ of the second partial product 122. A second AND logic gate 162 receives as input the first bit x₁ of the first operand X and the first bit y, of the second operand Y, and generates as output a first bit p₁ of the second partial product 122. A third AND logic gate 163 receives as input the second bit x₂ of the first operand X and the first bit y, of the second operand Y, and generates as output a second bit p₂ of the second partial product 122. A fourth AND logic gate 164 receives as input the third bit x₃ of the first operand X and the first bit y₁ of the second operand Y. The output of the fourth logic gate 164 is provided as input to an XOR logic gate 165. The XOR logic gate 165 further receives as input the signedness of the first operand X (signedness_x), and generates as output a third bit p₃ of the second partial product 122.

The second partial product 12₂ may be stored in any suitable computer-readable storage medium, including in a wire, register, computer-readable memory, or the like. Moreover, the second partial product 12₂ may be left-shifted by one position with respect to the first partial product 121, and in some implementations, the second partial product 12₂ may be stored in the left-shifted position with respect to the first partial product 121 or may be left-shifted during later operations to add the partial products.

The third partial product circuit 11₃ includes a first AND logic gate 171 that receives as input the zeroth bit x₀ of the first operand X and the second bit y₂ of the second operand Y, and generates as output a zeroth bit p₀ of the third partial product 123. A second AND logic gate 172 receives as input the first bit x₁ of the first operand X and the second bit y₂ of the second operand Y, and generates as output a first bit p₁ of the third partial product 123. A third AND logic gate 173 receives as input the second bit x₂ of the first operand X and the second bit y₂ of the second operand Y, and generates as output a second bit p₂ of the third partial product 123. A fourth AND logic gate 174 receives as input the third bit x₃ of the first operand X and the second bit y₂ of the second operand Y. The output of the fourth logic gate 174 is provided as input to an XOR logic gate 175. The XOR logic gate 175 further receives as input the signedness of the first operand X (signedness_x), and generates as output a third bit p₃ of the third partial product 123.

The third partial product 12₃ may be stored in any suitable computer-readable storage medium, including in a wire, register, computer-readable memory, or the like. The third partial product 12₃ may be left-shifted by one position with respect to the second partial product 122, and in some implementations, the third partial product 12₃ may be stored in the left-shifted position with respect to the second partial product 12₂ or may be left-shifted during later operations to add the partial products.

As shown, the first partial product circuit 111, the second partial product circuit 112, and the third partial product circuit 11₃ may be the same or substantially the same circuit arrangements. However, each of these circuits operates with different bits of operand input. More particularly, the first partial product circuit 111 multiplies the zeroth bit y₀ of the second operand Y with each of the bits of the first operand X, the second partial product circuit 112 multiplies the first bit y, of the second operand Y with each of the bits of the first operand X, and the third partial product circuit 11₃ multiplies the second bit y₂ of the second operand Y with each of the bits of the first operand X.

Similarly, the fourth partial product circuit 114 multiplies the third bit y₃ of the second operand Y with each of the bits of the first operand X; however, the circuitry of the fourth partial product circuit 114 is different than that of the first, second, and third partial product circuits 111, 112, 113, as the fourth partial product circuit 114 further performs a logical XOR operation with the signedness of the second operand Y (signedness_y) for each of the output multiplication bits.

As shown, the fourth partial product circuit 114 includes a first AND logic gate 181 that receives as input the zeroth bit x₀ of the first operand X and the third bit y₃ of the second operand Y. A second AND logic gate 182 receives as input the first bit x₁ of the first operand X and the third bit y₃ of the second operand Y. A third AND logic gate 183 receives as input the second bit x₂ of the first operand X and the third bit y₃ of the second operand Y. A fourth AND logic gate 184 receives as input the third bit x₃ of the first operand X and the third bit y₃ of the second operand Y. The output of the fourth logic gate 184 is provided as input to a first XOR logic gate 185. The first XOR logic gate 185 further receives as input the signedness of the first operand X (signedness_x).

The fourth partial product circuit 114 further includes a plurality of XOR logic gates configured to perform logical XOR operations using the signedness of the second operand Y (signedness_y) and the outputs of each of the first, second, and third AND logic gates and the XOR logic gate 185 as inputs. More particularly, the fourth partial product circuit 114 includes a second XOR logic gate 186 that generates a zeroth bit p₀ of the fourth partial product 124 based on the output of the first AND logic gate 181 and the signedness of the second operand Y (signedness_y). A third XOR logic gate 187 generates a first bit p₁ of the fourth partial product 124 based on the output of the second AND logic gate 182 and the signedness of the second operand Y (signedness_y). A fourth XOR logic gate 188 generates a second bit p₂ of the fourth partial product 124 based on the output of the third AND logic gate 183 and the signedness of the second operand Y (signedness_y). A fifth XOR logic gate 189 generates a third bit p₃ of the fourth partial product 124 based on the output of the first XOR logic gate 185 and the signedness of the second operand Y (signedness_y).

The fourth partial product 124 may be stored in any suitable computer-readable storage medium, including in a wire, register, computer-readable memory, or the like. The fourth partial product 124 may be left-shifted by one position with respect to the third partial product 123, and in some implementations, the fourth partial product 124 may be stored in the left-shifted position with respect to the third partial product 12₃ or may be left-shifted during later operations to add the partial products.

The binary multiplication circuit 100 further includes the correction factor circuit 125 that generates the correction factor 130 based on the signedness of the first and second operands. The correction factor circuit 125 includes an XOR logic gate 191 configured to generate a zeroth bit cf₀ of the correction factor 130 based on the signedness of the first and second operands (signedness_x, signedness_y). An AND logic gate 192 is configured to generate a first bit cf₁ of the correction factor 130 based on the signedness of the first and second operands (signedness_x, signedness_y). An OR logic gate 193 is configured to generate a fourth bit cf₄ of the correction factor 130 based on the signedness of the first and second operands (signedness_x, signedness_y).

Although two zeros are shown between the first bit cf₁ and the fourth bit cf₄ of the correction factor 130, it will be readily appreciated that any number of zeros may be positioned here depending on a number of bits of the first and second operands X, Y. Moreover, zeros may be inserted in other positions of the correction factor 130 in some implementations. More particularly, as previously described with respect to FIG. 1, the correction factor 130 includes 2N bits, which in the illustrated example is 8-bits, since each of the first and second operands X, Y are 4-bit numbers. The most significant bit, in this example the fourth bit cf₄ of the correction factor 130, is followed by N-2 zeroes. In the illustrated example, the number N is equal to 4, and thus 2 zeros follow the fourth bit cf₄, as shown. Further, as previously described with respect to FIG. 1, the correction factor 130 includes N-1 zeroes in the least significant bit positions. Thus, in the example shown in FIG. 2, the correction factor 130 may include 3 zeroes following the zeroth bit cf₀ of the correction factor 130.

The final multiplication result is obtained by binary addition of 121, 122, 123, 124, and 130.

Each of the inputs received by the various logic gates described herein may be digital signals that are transmitted, for example, via electrical wires or lines as illustrated.

The circuit 100 illustrated in FIG. 2 is described below with respect to performing binary multiplication on 4-bit operands; however, the present disclosure is not limited thereto, and in various implementations, the operands may have any number of bits. The circuit may be modified to include, for example, more AND gates to handle any bit length.

FIG. 3 illustrates a block diagram of an N-bit mixed sign multiplier 200 in accordance with some implementations of the disclosure. The N-bit mixed sign multiplier 200 inputs two N-bit length operands X and Y and the signednesses of each of the operands X and Y. The N-bit mixed sign multiplier 200 outputs a product P. In some implementations, the product P is 2N bits wide. The N-bit mixed sign multiplier 200 may be implemented using the methods and systems as described above in FIGS. 2 and 3 or the example device described below in FIG. 4.

FIG. 4 is a block diagram of an example device 400 in which one or more features of the disclosure can be implemented. The device 400 can include, for example, a computer, a gaming device, a handheld device, a set-top box, a television, a mobile phone, server, a tablet computer, or other types of computing devices. The device 400 includes a processor 402, a memory 404, a storage 406, one or more input devices 408, and one or more output devices 410. The device 400 can also optionally include an input driver 412 and an output driver 414. It is understood that the device 400 can include additional components not shown in FIG. 4.

In various alternatives, the processor 40₂ includes a central processing unit (CPU), a graphics processing unit (GPU), a CPU and GPU located on the same die, or one or more processor cores, wherein each processor core can be a CPU or a GPU. In various alternatives, the memory 40₄ is located on the same die as the processor 402, or is located separately from the processor 402. The memory 40₄ includes a volatile or non-volatile memory, for example, random access memory (RAM), dynamic RAM, or a cache.

The storage 40₆ includes a fixed or removable storage, for example, a hard disk drive, a solid-state drive, an optical disk, or a flash drive. The input devices 408 include, without limitation, a keyboard, a keypad, a touch screen, a touch pad, a detector, a microphone, an accelerometer, a gyroscope, a biometric scanner, or a network connection (e.g., a wireless local area network card for transmission and/or reception of wireless IEEE 802 signals). The output devices 410 include, without limitation, a display, a speaker, a printer, a haptic feedback device, one or more lights, an antenna, or a network connection (e.g., a wireless local area network card for transmission and/or reception of wireless IEEE 802 signals).

The input driver 412 communicates with the processor 40₂ and the input devices 408, and permits the processor 40₂ to receive input from the input devices 408. The output driver 414 communicates with the processor 40₂ and the output devices 410, and permits the processor 40₂ to send output to the output devices 410. It is noted that the input driver 412 and the output driver 414 are optional components, and that the device 400 will operate in the same manner if the input driver 412 and the output driver 414 are not present. The output driver 416 includes an accelerated processing device (“APD”) 416 which is coupled to a display device 418. The APD accepts compute commands and graphics rendering commands from processor 402, processes those compute and graphics rendering commands, and provides pixel output to display device 418 for display. As described in further detail below, the APD 416 includes one or more parallel processing units to perform computations in accordance with a single-instruction-multiple-data (“SIMD”) paradigm. Thus, although various functionality is described herein as being performed by or in conjunction with the APD 416, in various alternatives, the functionality described as being performed by the APD 416 is additionally or alternatively performed by other computing devices having similar capabilities that are not driven by a host processor (e.g., processor 402) and provides graphical output to a display device 418. For example, it is contemplated that any processing system that performs processing tasks in accordance with a SIMD paradigm can perform the functionality described herein. Alternatively, it is contemplated that computing systems that do not perform processing tasks in accordance with a SIMD paradigm can also perform the functionality described herein.

FIG. 5 illustrates an example method for performing digital multiplication in accordance with implementations of the disclosure. The method of FIG. 5 may be combined with other methods and performed using the systems and apparatuses as described herein. For example, the method of FIG. 5 may be combined with any of the implementations of FIGS. 1-4. Although shown in a logical order, the arrangement and numbering of the steps of FIG. 5 are not intended to be limited. The method steps of FIG. 5 may be performed in any suitable order or concurrently with one another as may be apparent to a person of skill in the art.

Referring to FIG. 5, a method 500 for performing a binary multiplication includes receiving steps 502 and 504 of receiving a first operand having N bits at an input interface of a digital multiplier circuit and receiving a second operand having M bits at the input interface of the digital multiplier circuit. A generation step 506 includes generating M N-bit partial products by performing a logical AND operation with each of the N bits of the first operand and each of the M bits of the second operand. Modified partial product steps 508 and 510 include generating first modified M partial products by modifying Nth bits of the M partial products and generating second modified M partial products by modifying the Mth partial product. In a correction factor step 512, a correction factor having (N+M) bits is generated by the digital multiplier circuit. In a summing step 514, a product having (N+M) bits is generated by the digital multiplier circuit by summing the second modified partial products and the correction factor. Output step 516 includes outputting the product from an output interface of the digital multiplier circuit, the product having (N+M) bits.

Various example implementations are provided in the following. Other implementations may be understood from the entirety of the specification as well as the claims filed herein.

Implementations may achieve advantages. The described methods and systems have the benefit that this mixed sign multiplier is more efficient in power, performance, and area compared to known multipliers. For example, the disclosed implementations of the mixed sign multiplier, when compared to current multipliers, reduces the required area by 11.6% while using 28% less power. Moreover, the disclosed multiplier is able to handle inputs of any signedness (both signed, both unsigned, or one signed and one unsigned). For example, with implementations of the disclosed methods and systems, a single multiplier can handle the multiplication of FP16 and INT8 datatypes, with the disclosed implementations, a single mixed sign 11×11 multiplier can be used—as signed 8×8 multiplication is a subset of this multiplier.

An implementation may include a method for performing a binary multiplication including receiving a first operand having N bits at an input interface of a digital multiplier circuit in the computing system, receiving a second operand having M bits at the input interface of the digital multiplier circuit, generating, by the digital multiplier circuit, M N-bit partial products by performing a logical AND operation with each of the N bits of the first operand and each of the M bits of the second operand, and generating first modified M partial products by modifying, by the digital multiplier circuit, Nth bits of the M partial products, generating second modified M partial products by modifying, by the digital multiplier circuit, the Mth first modified partial product, generating, by the digital multiplier circuit, a correction factor having (N+M) bits, generating, by the digital multiplier circuit, a product by summing the second modified partial products and the correction factor, and outputting the product from an output interface of the digital multiplier circuit, the product having (N+M) bits.

Implementations may include one or more of the following features. The method where generating first modified M partial products by modifying, by the digital multiplier circuit, the Nth bits of the M partial products includes performing a logical XOR of each of the Nth bits of the M partial products with a signedness of the first operand to generate the first modified M partial products. The method where the signedness of the first operand is a bit value of ‘1’ when the first operand is a signed number, and wherein the signedness of the first operand is a bit value of ‘0’ when the first operand is an unsigned number. The method where generating second modified M partial products by modifying, by the digital multiplier circuit, the Mth first modified partial product includes performing a logical XOR of each of the N bits of the Mth first modified partial product with a signedness of the second operand to generate the second modified M partial products. The method where the signedness of the second operand is a bit value of ‘1’ when the second operand is a signed number, and wherein the signedness of the second operand is a bit value of ‘0’ when the second operand is an unsigned number. The method where receiving the first operand includes receiving a signed number or an unsigned number, and wherein receiving the second operand includes receiving a number having the other signedness option as the first operand. The method further including left-shifting each of the M partial products one bit position with respect to a prior partial product. The method where generating, by the digital multiplier circuit, a correction factor having (N+M) bits includes generating a bit mask of the (N+M) bits for the correction factor, the bit mask being generated according to Correction Factor={OR of signednesses of the first and second operands, N-2 zeroes, AND of signednesses of first and second operands, XOR of signednesses of the first and second operands, M-1 zeroes}. The method where the computing system includes an application-specific integrated circuit (ASIC), a field-programmable gate array (FPGA), a CPU, a GPU, a general-purpose computing on GPU (GPGPU), an AI engine, a digital signal processing (DSP) system, or a neural network.

An implementation may include a device for performing a binary multiplication, the device including a digital multiplier circuit configured to: receive a first operand having N bits at an input interface, receive a second operand having N bits at the input interface, generate N partial products by performing a logical AND operation with each of the N bits of the first operand and each of the N bits of the second operand, generate first modified N partial products by modifying Nth bits of the N partial products, generate second modified N partial products by modifying the Nth partial product, generate a correction factor having 2N bits, generate a product by summing the second modified partial products and the correction factor, and output the product from an output interface, the product having 2N bits.

Implementations may include one or more of the following features. The device where the digital multiplier circuit is further configured to perform a logical XOR of each of the Nth bits of the N partial products with a signedness of the first operand to generate the first modified N partial products. The device where the digital multiplier circuit is further configured to perform a logical XOR of each of the N bits of the Nth partial product with a signedness of the second operand to generate the second modified N partial products. The device where the digital multiplier circuit is further configured to receive the first operand being a signed number or an unsigned number, and the second operand being the other signedness option as the first operand. The device where the digital multiplier circuit is further configured to left-shift each of the N partial products by one bit position with respect to a prior partial product. The device where the digital multiplier circuit is further configured to generate a bit mask of the 2N bits for the correction factor, the bit mask being generated by according to Correction Factor={OR of signednesses of the first and second operands, N-2 zeroes, AND of signednesses of first and second operands, XOR of signednesses of the first and second operands, N-1 zeroes}. The device where the device includes an application-specific integrated circuit (ASIC), a field-programmable gate array (FPGA), a CPU, a GPU, a general-purpose computing on GPU (GPGPU), an AI engine, a digital signal processing (DSP) system, or a neural network.

An implementation may include a binary multiplication circuit including a plurality of partial product circuits configured to generate partial products of a first operand and a second operand, each of the partial product circuits including AND operators with each of the AND operators having inputs including a corresponding one of bits of the second operand and each of bits of the first operand, a first partial product modifier circuit including a plurality of XOR operators, each of the XOR operators of the first partial product modifier circuit having two inputs, each of first inputs being a signedness of the first operand, each of second inputs being an output of a most significant bit AND operator of a corresponding partial product circuit, a second partial product modifier circuit including a plurality of XOR operators, each of the XOR operators of the second partial product modifier circuit having two inputs, each of first inputs being a signedness of the second operand, one of the plurality of XOR operators of the second partial product modifier circuit having a second input of an output of an XOR operator of the first partial product modifier circuit associated with one of the plurality of partial product circuits, each of the XOR operators of the second partial product modifier circuit having second inputs of an output of corresponding bits of one of the plurality of partial product circuits, and a binary adder circuit configured to add outputs of the partial product circuits and the first and second partial product modifier circuits.

Implementations may include one or more of the following features. The binary multiplication circuit including a correction factor circuit configured to generate a bit mask of (N+M) bits, the bit mask being {OR of the signednesses of the first and second operands, N-2 zeroes, AND of the signednesses of first and second operands, XOR of the signednesses of the first and second operands, M-1 zeroes}, where the binary adder circuit is configured to add the outputs of the partial product circuits, the first and second partial product modifier circuits, and the correction factor circuit, wherein the first operand is N-bits and the second operand is M bits. The binary multiplication circuit where the first operand includes a signed number or an unsigned number, and wherein the second operand includes a number having the other signedness option as the first operand. The binary multiplication circuit where the adder circuit further includes a left-shifting circuit configured to left-shift each of the partial products one bit position with respect to a prior partial product.

While this invention has been described with reference to illustrative implementations, this description is not intended to be construed in a limiting sense. Various modifications and combinations of the illustrative implementations, as well as other implementations of the invention, will be apparent to persons skilled in the art upon reference to the description. It is therefore intended that the appended claims encompass any such modifications or implementations.

What is claimed is:

1. A method for performing a binary multiplication in a computing system, the method comprising:
receiving a first operand having N bits at an input interface of a digital multiplier circuit in the computing system;
receiving a second operand having M bits at the input interface of the digital multiplier circuit;
generating, by the digital multiplier circuit, M N-bit partial products by performing a logical AND operation with each of the N bits of the first operand and each of the M bits of the second operand; and
generating first modified M partial products by modifying, by the digital multiplier circuit, Nth bits of the M partial products;
generating second modified M partial products by modifying, by the digital multiplier circuit, the Mth first modified partial product;
generating, by the digital multiplier circuit, a correction factor having (N+M) bits;
generating, by the digital multiplier circuit, a product by summing the second modified partial products and the correction factor; and
outputting the product from an output interface of the digital multiplier circuit, the product having (N+M) bits.

2. The method of claim 1, wherein generating first modified M partial products by modifying, by the digital multiplier circuit, the Nth bits of the M partial products comprises:
performing a logical XOR of each of the Nth bits of the M partial products with a signedness of the first operand to generate the first modified M partial products.

3. The method of claim 2, wherein the signedness of the first operand is a bit value of ‘1’ when the first operand is a signed number, and wherein the signedness of the first operand is a bit value of ‘0’ when the first operand is an unsigned number.

4. The method of claim 2, wherein generating second modified M partial products by modifying, by the digital multiplier circuit, the Mth first modified partial product comprises:
performing a logical XOR of each of the N bits of the Mth first modified partial product with a signedness of the second operand to generate the second modified M partial products.

5. The method of claim 4, wherein the signedness of the second operand is a bit value of ‘1’ when the second operand is a signed number, and wherein the signedness of the second operand is a bit value of ‘0’ when the second operand is an unsigned number.

6. The method of claim 1, wherein receiving the first operand comprises receiving a signed number or an unsigned number, and wherein receiving the second operand comprises receiving a number having the other signedness option as the first operand.

7. The method of claim 1, further comprising:
left-shifting each of the M partial products one bit position with respect to a prior partial product.

8. The method of claim 1, wherein generating, by the digital multiplier circuit, a correction factor having (N+M) bits comprises:
generating a bit mask of the (N+M) bits for the correction factor, the bit mask being generated according to:
Correction Factor={OR of signednesses of the first and second operands, N-2 zeroes, AND of signednesses of first and second operands, XOR of signednesses of the first and second operands, M-1 zeroes}.

9. The method of claim 1, wherein the computing system comprises an application-specific integrated circuit (ASIC), a field-programmable gate array (FPGA), a CPU, a GPU, a general-purpose computing on GPU (GPGPU), an AI engine, a digital signal processing (DSP) system, or a neural network.

10. A device for performing a binary multiplication, the device comprising:
a digital multiplier circuit configured to:
receive a first operand having N bits at an input interface;
receive a second operand having N bits at the input interface;
generate N partial products by performing a logical AND operation with each of the N bits of the first operand and each of the N bits of the second operand;
generate first modified N partial products by modifying Nth bits of the N partial products;
generate second modified N partial products by modifying the Nth partial product;
generate a correction factor having 2N bits;
generate a product by summing the second modified partial products and the correction factor; and
output the product from an output interface, the product having 2N bits.

11. The device of claim 10, wherein the digital multiplier circuit is further configured to:
perform a logical XOR of each of the Nth bits of the N partial products with a signedness of the first operand to generate the first modified N partial products.

12. The device of claim 11, wherein the digital multiplier circuit is further configured to:
perform a logical XOR of each of the N bits of the Nth partial product with a signedness of the second operand to generate the second modified N partial products.

13. The device of claim 10, wherein the digital multiplier circuit is further configured to:
receive the first operand being a signed number or an unsigned number, and the second operand being the other signedness option as the first operand.

14. The device of claim 10, wherein the digital multiplier circuit is further configured to:
left-shift each of the N partial products by one bit position with respect to a prior partial product.

15. The device of claim 10, wherein the digital multiplier circuit is further configured to:
generate a bit mask of the 2N bits for the correction factor, the bit mask being generated by according to:
Correction Factor={OR of signednesses of the first and second operands, N-2 zeroes, AND of signednesses of first and second operands, XOR of signednesses of the first and second operands, N-1 zeroes}.

16. The device of claim 10, wherein the device comprises an application-specific integrated circuit (ASIC), a field-programmable gate array (FPGA), a CPU, a GPU, a general-purpose computing on GPU (GPGPU), an AI engine, a digital signal processing (DSP) system, or a neural network.

17. A binary multiplication circuit, comprising:
a plurality of partial product circuits configured to generate partial products of a first operand and a second operand, each of the partial product circuits comprising AND operators with each of the AND operators having inputs comprising a corresponding one of bits of the second operand and each of bits of the first operand;
a first partial product modifier circuit comprising a plurality of XOR operators, each of the XOR operators of the first partial product modifier circuit having two inputs, each of first inputs being a signedness of the first operand, each of second inputs being an output of a most significant bit AND operator of a corresponding partial product circuit;
a second partial product modifier circuit comprising a plurality of XOR operators, each of the XOR operators of the second partial product modifier circuit having two inputs, each of first inputs being a signedness of the second operand, one of the plurality of XOR operators of the second partial product modifier circuit having a second input of an output of an XOR operator of the first partial product modifier circuit associated with one of the plurality of partial product circuits, each of the XOR operators of the second partial product modifier circuit having second inputs of an output of corresponding bits of one of the plurality of partial product circuits; and
a binary adder circuit configured to add outputs of the partial product circuits and the first and second partial product modifier circuits.

18. The binary multiplication circuit of claim 17, further comprising:
a correction factor circuit configured to generate a bit mask of (N+M) bits, the bit mask being {OR of the signednesses of the first and second operands, N-2 zeroes, AND of the signednesses of first and second operands, XOR of the signednesses of the first and second operands, M-1 zeroes},
wherein the binary adder circuit is configured to add the outputs of the partial product circuits, the first and second partial product modifier circuits, and the correction factor circuit, wherein the first operand is N-bits and the second operand is M bits.

19. The binary multiplication circuit of claim 17, wherein the first operand comprises a signed number or an unsigned number, and wherein the second operand comprises a number having the other signedness option as the first operand.

20. The binary multiplication circuit of claim 17, wherein the adder circuit further comprises:
a left-shifting circuit configured to left-shift each of the partial products one bit position with respect to a prior partial product.
